(19) United States
(12) Patent Application Publication
(10) Pub. No.: US 2025/0174457 A1
(43) Pub. Date: May 29, 2025

(54) METHODS FOR DEPOSITING A BORON DOPED SILICON GERMANIUM LAYER AND ASSOCIATED COMPOSITIONS

(71) Applicant: ASM IP Holding B.V., Almere (NL)

(72) Inventors: Lutz Muehlenbein, Phoenix, AZ (US); Rami Khazaka, Leuven (BE); Patricio Romero, Wilsele (BE); Brendan Marozas, Leuven (BE); Daniel Casey, Herent Flemish Brabant (BE)

(21) Appl. No.: 18/962,342

(22) Filed: Nov. 27, 2024

Related U.S. Application Data
(60) Provisional application No. 63/604,010, filed on Nov. 29, 2023.

(51) Int. Cl. H01L 21/02; H10D 62/13

(52) U.S. Cl. CPC H01L 21/02579; H01L 21/02532; H10D 62/149

(57) ABSTRACT

Methods for depositing boron doped silicon germanium layers and associated compositions are disclosed. The methods include depositing the boron doped silicon germanium layers by a thermal deposition process employing a composition including a iodosilane precursor. The methods also include depositing the boron doped silicon germanium layers by selective deposition processes.

### CROSS-REFERENCE TO RELATED APPLICATION(S)

This application claims the benefit of U.S. Provisional Application 63/604,010 filed on Nov. 29, 2023, the entire contents of which are incorporated herein by reference.

### FIELD

The present disclosure relates generally to the field of semiconductor processing methods, and associated structures and compositions, and to the field of device and integrated circuit manufacture. In particular, the present the disclosure generally relates to methods for depositing boron doped silicon germanium layers and associated compositions employed in the deposition processes.

### BACKGROUND

Silicon germanium (SiGe) layers are increasingly employed in semiconductor devices due in part to such high mobility layers improving device performance, speed, power consumption, and breakdown fields compared to similar devices fabrication with lower mobility semiconductors, such as silicon, for example.

A variety of deposition processes can be utilized for the deposition of silicon germanium layers, including chemical vapor deposition, molecular beam epitaxy, and physical vapor deposition, for example. In particular, epitaxial deposition processes can be used to deposit monocrystalline silicon germanium layers. The deposition of silicon germanium layers can also include doping the layers with select impurities to improve/control the layers electrical characteristics. For example, SiGe layers can be doped p-type by the incorporation of boron into the SiGe layer.

However, improvements in deposition methods and associated gas compositions used for depositing silicon germanium layers are needed to maintain or even improve device/integrated circuit performance as device density increases and substrate real estate decreases. Accordingly, improved deposition methods and associated deposition gas compositions are desirable for enabling the deposition of enhanced silicon germanium layers.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods and associated gas compositions for thermally depositing boron doped silicon germanium layers with both a high active dopant concentration and a high germanium content. As set forth in more detail below, the methods and associated compositions described herein enable the deposition of boron doped silicon germanium layers having both a high active dopant concentration and a high germanium content.

In accordance with examples of the disclosure a method of thermally depositing a boron doped silicon germanium layer with both a high active dopant concentration and a high germanium content is provided. In such examples the method includes, seating a substrate in a reaction chamber, heating the substrate to a deposition temperature, and depositing the boron doped silicon germanium layer on a surface of the substrate by an epitaxial deposition process. In such examples, the epitaxial deposition process includes introducing a germanium precursor into the reaction chamber, introducing a boron precursor into the reaction chamber, and introducing a silicon precursor including an iodosilane precursor into the reaction chamber. In accordance with examples of the disclosure, the deposition temperature is between 250° C. and 400° C. In such examples the boron doped silicon germanium layer is deposited with an average layer thickness between 5 nm and 20 nm at growth rate between 1 nm/min and 10 nm/min. In accordance with examples of the disclosure, the germanium precursor includes a germanium chloride compound selected from the group consisting of GeCl₄, GeCl₂, and GeCl₂H₂. In accordance with examples of the disclosure, the boron precursor includes a boron chloride compound selected from the group consisting of BH₂Cl, BCl₂H, and BCl₃. In accordance with examples of the disclosure, the iodosilane precursor is selected from the group consisting of monoiodosilane, diiodosilane, triiodosilane, tetraiodosilane. In accordance with examples of the disclosure, the iodosilane precursor consists of diiodosilane. In accordance with examples of the disclosure, the iodosilane precursor consists of monoiodosilane. In accordance with examples of the disclosure, the substrate comprises a silicon germanium source/drain region and the boron doped silicon germanium layer is epitaxially deposited directly on the silicon germanium source/drain region. In accordance with examples of the disclosure, the boron doped silicon germanium layer has both an active dopant concentration greater than 3×10²¹ cm³ and a germanium content greater than 50 atomic-%. In accordance with examples of the disclosure, the epitaxial deposition process is a selective deposition process which selectively deposits the boron doped silicon germanium layer on a surface A relative to a surface B. In such examples, the surface A is a silicon nitride surface and the surface B is a silicon oxide surface, or the surface A is silicon oxide surface or a silicon nitride surface and the surface B is a silicon surface. In such examples the method further includes introducing an etchant into the reaction chamber. In such examples the selective deposition process further includes a cyclical deposition process or a cyclical deposition-etch process.

In accordance with additional examples of the disclosure a method of forming a contact layer to a silicon germanium source/drain region is provided. In such examples the method includes seating a substrate in a reaction chamber, the substrate including one or more silicon germanium source/drain regions, and heating the substrate to a deposition temperature between 250° C. and 400° C. In such examples, the method includes depositing a boron doped silicon germanium layer on the silicon germanium source/drain region by an epitaxial deposition process by introducing a single silicon precursor comprising an iodosilane precursor, a germanium precursor, and a boron precursor into the reaction chamber. In such examples, the boron doped silicon germanium layer has both an active dopant concentration greater than 3×10²¹ cm³ and a germanium content greater than 50 atomic-%. In accordance with examples of the disclosure, at least one of the germanium precursor and the boron precursor includes a chloride compounds. In accordance with examples of the disclosure, the epitaxial deposition process is a selective deposition process which selectively deposits the boron doped silicon germanium layer on a surface A relative to a surface B. In such examples, the surface A is a silicon nitride surface and the surface B is a silicon oxide surface, or the surface A is a silicon oxide surface or a silicon nitride surface and the surface B is a silicon surface. In accordance with examples of the disclosure, the iodosilane precursor consists of diiodosilane or monoiodosilane.

In accordance with additional examples of the disclosure a composition for epitaxial deposition of a boron doped silicon germanium layer with both an active dopant concentration greater than 3×10²¹ cm⁻³ and a germanium content greater than 50 atomic-% is provided. In such examples the composition includes an iodosilane precursor having less than 1% metal impurities and less than 1% phosphorous impurities. In some embodiments, the composition consists essentially of the iodosilane precursor, a germanium precursor, a boron precursor, and one or more additional inert gases. In such examples the iodosilane precursor is diiodosilane or monoiodosilane. In such examples the germanium precursor includes a germanium chloride compound selected from the group consisting of GeCl₄, GeCl₂, and GeCl₂H₂. In such examples the boron precursor comprises a boron chloride compound selected from the group consisting of BH₂Cl, BCl₂H, and BCl₃.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates an exemplary method for depositing boron doped silicon germanium layers in accordance with one or more embodiments of the disclosure.

FIG. 2 illustrates an exemplary method for selectively depositing boron doped silicon germanium layers in accordance with one or more embodiments of the disclosure.

FIG. 3 illustrates a structure including a substrate in accordance with one or more embodiments of the disclosure.

FIG. 4 illustrates a structure including a source/drain region in accordance with one or more embodiments of the disclosure.

FIG. 5 illustrates a structure including a boron doped silicon germanium layer in accordance with one or more embodiments of the disclosure.

FIG. 6 illustrates a structure including a metal layer in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “film” and/or “layer” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gases. Exemplary seal gases include noble gasses, nitrogen, and the like. In some cases, the term “precursor” can refer to a compound that participates in the chemical reaction that produces another compound, and particularly to a compound that constitutes a film matrix or a main skeleton of a film. In addition, the term “reactant” can be used interchangeably with the term “precursor”.

As used herein, the term “epitaxial layer” can refer to a substantially single crystalline layer directly on a underlying substantially single crystalline substrate or layer.

As used herein, the term “chemical vapor deposition” can refer to any process wherein a substrate is exposed to one or more volatile precursors (as well as optional additional process gases), which react and/or decompose on a substrate surface to produce a desired deposition.

As used here, the term “silicon germanium” can refer to a semiconductor material comprising silicon and germanium and can be represented as Si₁₋ₓGeₓ wherein 1≥x≥0, or 0.8≥x≥0.1, or 0.6≥x≥0.2, or materials comprising silicon and germanium having compositions as set forth herein. In addition the term “silicon germanium” can be represented as SiGe and can further be represented as SiGe: B when said silicon germanium is doped with a boron dopant. Likewise a silicon material doped with a boron dopant can be represented as Si: B.

As used herein, the term “fully strained” can refer to an epitaxially deposited layer of a first material which is lattice matched to an underlying crystalline substrate or crystalline layer of a second material, wherein the first material is composed of a different material and/or a different composition of material, to the second material. A “fully strained” epitaxially deposited layer has not undergone strain relaxation and is therefore free, or substantially free, of strain relaxation induced dislocations.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

Various embodiments of the present disclosure relate to methods and compositions for depositing boron doped silicon germanium layers (SiGe: B). As set forth in more detail below, the methods and associated compositions of the present disclosure deposit SiGe: B layers with both a high active dopant concentration and a high germanium content employing chemical vapor deposition processes, such as, epitaxial deposition processes, for example. The epitaxial deposition processes of the present disclosure can employ a composition (e.g., a deposition gas composition) comprising an iodosilane precursor as the silicon precursor (either as the single silicon precursor or with the addition of other silicon precursors). The epitaxial deposition methods of the present disclosure also include selective epitaxial deposition processes where the deposited SiGe: B layers are preferentially deposited on a first surface (surface A) relative to a second surface (surface B). In such examples, the selective epitaxial deposition processes can include cyclical deposition processes or cyclical deposition-etch processes.

As device density increases in integrated circuits (e.g., logic device and circuits), the area between the source/drain regions of the transistors and the metal interconnect layers (e.g., middle-of-the-line) continues to shrink. This reduction in area for interconnecting devices can limit device performance as the contact resistivity (pc) becomes increasing dominant. Therefore, the embodiments of the present disclosure also provide methods to reduce contact resistivity (pc) by enabling the depositing of boron doped silicon germanium layers with both a high active dopant concentration and a high germanium content. In such embodiments, the contact resistivity (pc) can be reduced by raising the active doping concentration in the source/drain regions. Further, in such examples, the contact resistivity (pc) can be reduced by decreasing the Schottky Barrier Height (SBH) between source/drain regions and a metal of the interconnecting layer.

In more detail, and in accordance with examples of the disclosure, a thin contact layer comprising a boron doped silicon germanium layer can be deposited on the source/drain regions of the transistor structures. In such examples, the thin contact layer comprises SiGe: B layers of the present disclosure (i.e., with both high germanium and active dopant concentrations). Further in such examples, the contact layer can be kept thin (e.g., below X nm) and as such the lattice mismatch between the contact layer and the underlying layers can be better controlled thereby maintaining the strain across the contact layer without the formation (or reduced formation) of defects, such as misfit dislocations, for example. In addition, the high active dopant concentration in the SiGe: B layers of the present disclosure can assist in compensating strain induced by the high germanium content in the SiGe: B layers.

Common deposition methods are unable to successfully obtain both the high active donor concentrations and germanium content enable by the present disclosure. For example, common methods for the deposition of SiGe: B layers often result in a plateau and eventually a reduction in active dopant concentration as the germanium content is increased in the SiGe: B layer.

Therefore, in accordance with examples of the present disclosure, methods are provided for depositing boron doped silicon germanium layers with both a high active dopant concentration and a high germanium content by employing a composition (e.g., a deposition gas composition or deposition gas formulation) that includes an iodosilane precursor. In such examples, the methods and compositions disclosed herein can increase the active doping concentration in the deposited boron doped silicon germanium layers above 3×10²¹ cm⁻³ while keeping the germanium concentration in the SiGe: B layer above 50%.

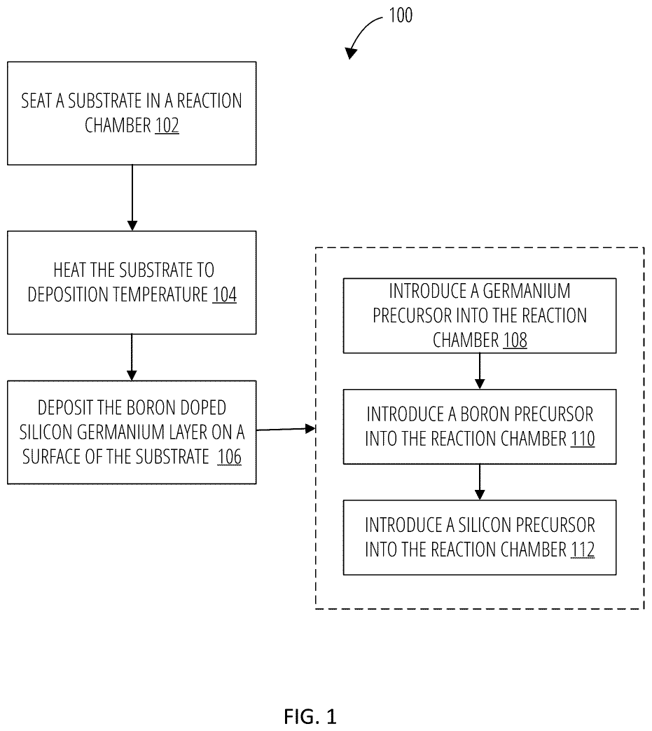

Turning now to the figures, FIG. 1 illustrates an exemplary method 100 for depositing boron doped silicon germanium layers with both a high active dopant concentration and a high germanium content according to the embodiments of the present disclosure. Briefly, method 100 includes the steps of, seating a substrate within a reaction chamber (step 102), heating the substrate to a deposition temperature (step 104), and depositing the boron doped silicon germanium layer on a surface of the substrate (step 106) by, introducing a germanium precursor into the reaction chamber (step 108), introducing a boron precursor into the reaction chamber (step 110), and introducing a silicon precursor comprising an iodosilane precursor into the reaction chamber (112).

In more detail and in accordance with examples of the disclosure, the method 100 includes step 102 which comprises seating a substrate in a reaction chamber. In such examples, the reaction chamber may comprise a reaction chamber of a chemical vapor deposition system. However, it is also contemplated that other reaction chambers (such as, for example, atomic layer deposition reaction chambers) and alternative chemical vapor deposition systems may also be utilized to perform the embodiments of the present disclosure. In some embodiments, the reaction chamber is configured for performing epitaxial deposition processes. In some embodiments, the reaction chamber may form part of a cluster-type semiconductor processing system, which can include multiple process modules for performing various semiconductor processing operations. In such embodiments, the cluster-type semiconductor processing system can include two or more reaction chambers configured to perform the epitaxial deposition processes of the present disclosure.

In accordance with examples of the disclosure, method 100 includes step 104 which comprises heating the substrate to a deposition temperature. In some embodiments of the disclosure, the deposition temperature (e.g., the substrate temperature during deposition) is less than 500° C., less than 450° C., less than 400° C., less than 350° C., less than 300° C., less than 250° C., or less than 200° C. In some embodiments of the disclosure, the deposition temperature is between 200° C. and 500° C., between 200° C. and 450° C., between 200° C. and 450° C., between 250° C. and 400° C., or between 250° C. and 350° C.

In addition to controlling the temperature of the substrate, the pressure within the reaction chamber can also be regulated. For example, in some embodiments of the disclosure, the pressure within the reaction chamber during deposition is less than 760 Torr, less than 350 Torr, less than 100 Torr, less than 50 Torr, less than 25 Torr, less than 10 Torr, or less than 5 Torr. In some embodiments, the pressure in the chamber body during deposition is between 5 Torr and 760 Torr, or between 10 Torr and 200 Torr, or between 20 Torr and 100 Torr.

In accordance with examples of the disclosure, method 100 includes step 106 which comprises depositing a boron doped silicon germanium layer on a surface of the substrate. In some embodiments of the disclosure, the deposition process (step 106) is a thermal deposition process which is performed within the reaction chamber without the use of excited species generated from a plasma, i.e., the deposition process is a thermal deposition process performed in a plasma-free environment. In some embodiments, the deposition process is a chemical vapor deposition (CVD) process. In such embodiments, the chemical vapor deposition process can be an epitaxial deposition process.

In accordance with examples of the disclosure, depositing the boron doped silicon germanium layer (step 106) comprises the following steps, introducing a germanium precursor into the reaction chamber (step 108), introducing a boron precursor in the reaction chamber (step 110), and introducing a silicon precursor comprising an iodosilane precursor into the reaction chamber (step 112). In some embodiments, step 108, step 110, and step 112 are performed in parallel, or at least partially in parallel. In other words, in some embodiments, the germanium precursor, the boron precursor, and the iodosilane precursor are introduced into reaction chamber together or at least with some overlap in the time of injection (i.e., temporal overlap) of the germanium precursor, the boron precursor, and the iodosilane precursor. In other embodiments of the disclosure, step 108, step 110, and step 112 can be performed in a sequence without any substantial overlap between each process step. In such embodiments, the step 108, step 110, and step 112 can be performed in any order and can include repeatedly performing one or more of steps 108, 110, and 112. In other embodiments, step 108, step 110, and step 112 can be performed as part of a repeating deposition cycle (i.e., a cyclical deposition process) and in such examples, one or more additional steps can be added to the deposition cycle (as is described in more detail below).

In accordance with examples of the disclosure, step 108 comprises introducing a germanium precursor into the reaction chamber. In such examples, the germanium precursor can include germanes, such as germane (GeH₄), digermane (Ge₂H₆), trigermane (Ge₃H₃), or germylsilane (GeH(Si). In accordance with examples of the disclosure, the germanium precursor can comprise a germanium halide compound. In such examples, the germanium precursor comprises a germanium chloride compound. Further in such examples, the germanium chloride compound is selected from a group consisting of GeCl₄, GeCl₂, and GeCl₂H₂. In some embodiments, two or more germanium precursors are introduced into reaction chamber during step 108. In such embodiments, the two or more germanium precursors can comprise germanes, germanium chloride compounds, or a mixture of both germanes and germanium chloride compounds.

In accordance with further examples of the disclosure, step 110 comprises introducing a boron precursor into the reaction chamber. In such examples, the boron precursor can include boranes, such as diborane (B₂H₆), or deuterium-diborane (B₂D₆). In accordance with examples of the disclosure, the boron precursor can comprise a boron halide compound. In such examples, the boron precursor comprises a boron chloride compound. Further in such examples, the boron chloride compound is selected from a group consisting of BH₂Cl, BCl₂H, and BCl₃. In some embodiments, two or more boron precursors are introduced into reaction chamber during step 110. In such embodiments, the two or more boron precursors can comprises boranes, boron chloride compounds, or a mixture of both boranes and boron chloride compounds.

In accordance with further examples of the disclosure, step 112 comprises introducing a silicon precursor into the reaction chamber. In some embodiments, step 112 comprises introducing a silicon precursor comprising an iodosilane precursor into the reaction chamber.

In some embodiments, step 112 comprises introducing a silicon precursor comprising an iodosilane precursor and an additional silicon precursor into the reaction chamber. In some embodiments, step 112 comprises introducing a single silicon precursor consisting of an iodosilane precursor into the reaction chamber. In some embodiments, step 112 comprises introducing a silicon precursor comprising two or more iodosilane precursors into the reaction chamber.

In accordance with examples of the disclosure, the silicon precursor can comprise a compound having a chemical formula including silicon (Si), hydrogen (H), and a halide. In such examples, the silicon precursor can comprise a compound having a chemical formula including silicon (Si), hydrogen (H), and iodine (I). In such examples, the silicon precursor can comprise a iodosilane precursor. In such examples, the iodosilane precursor is selected from a group consisting of monoiodosilane, diiodosilane, triiodosilane, and tetraiodosilane. In some embodiments, the silicon precursor consists of monoiodosilane. In some embodiments, the silicon precursor consists of diiodosilane. In some embodiments, the silicon precursor consists of triiodosilane. In some embodiments, the silicon precursor consists of tetraiodosilane.

In accordance with examples of the disclosure, the silicon precursor can comprise monoiodosilane In such examples, the monoiodosilane silicon precursor can have a higher vapor pressure than a diiodosilane silicon precursor (at a particular deposition temperature) which can lead to a higher concentration of the silicon precursor delivered to the reaction chamber. In such examples, the monoiodosilane silicon precursor can form an intermediate reaction product SiHI rather than a SiI₂ intermediate, which may promote a higher growth rate of the boron doped silicon germanium layer on the substrate, for example on a substrate including a silicon surface. Therefore, in some embodiments, the silicon precursor consists of monoiodosilane.

In accordance with examples of the disclosure, the silicon precursor can comprise a higher order iodosilane precursor. Not to limited by any theory or process, a higher order iodosilane precursor can include a weaker Si-Si bond which may provide benefits in the deposition of the boron doped silicon germanium layers of the present disclosure. In such examples, the silicon precursor can comprise a higher order iodosilane precursor, such as, but not limited to, diiodosilane, triiodosilane, and tetraiodosilane. In some embodiments, the silicon precursor comprises an iodosilane precursor with the general formula SiHₙI₍₄₋ₙ₎.

As described above, the silicon precursor can comprise two or more silicon precursors. In such examples, the silicon precursor can comprise an iodosilane precursor and one or more additional silicon precursors. In some embodiments, the silicon precursor can comprise an iodosilane precursor and one additional silicon precursor. In some embodiments the additional silicon precursor can include a hydrogenated silicon precursor. In such embodiments, the hydrogenated silicon precursor is selected from the group consisting of silane (SiH₄), disilane (Si₂H₆), trisilane (Si₃H₈), and tetrasilane (Si₄H₁₀). In some embodiments, the additional silicon precursor can comprise a silicon halide precursor. In accordance with examples of the disclosure, the silicon halide precursor can comprise a silicon chloride precursor. In such examples, the silicon chloride precursor is selected from a group consisting of monochlorosilane (MCS), dichlorosilane (DCS), trichlorosilane (TCS), hexachlorodisilane (HCDS), octachlorotrisilane (OCTS), and silicon tetrachloride (STC). Some of the benefits of the addition of a silicon halide precursor to the silicon precursor are described in greater detail below.

In accordance with examples of the disclosure, the boron doped silicon germanium layer is deposited at growth rate of greater than 0.5 nm/min, greater than 1 nm/min, greater than 1.5 nm/min, greater than 2 nm/min, greater than 2.5 nm/min, greater than 3 nm/min, greater than 4 nm/min, greater than 5 nm/min, greater than 6 nm/min, greater than 8 nm/min, or greater than 10 nm/min, or between 1 nm/min and 10 nm/min.

The various embodiments of the disclosure also include methods for selectively depositing boron doped silicon germanium layers by employing selective deposition processes. In accordance with examples of the disclosure, the selective deposition process comprises a selective chemical vapor deposition process. In some embodiments, the selective deposition process comprises a selective epitaxial deposition process. In such examples, the selective epitaxial deposition process selectively (i.e., preferentially) deposits a boron doped silicon germanium layer on a first surface (surface A) relative to a second surface (surface B).

The skilled artisan will appreciate that selective deposition can be fully selective or partially selective. A partially selective process can result in fully selective layer by a post-deposition etch that removes all of the deposited material from over surface B without removing the entirety of the deposited material from over surface A. Because an etch back process can leave a fully selective structure without the need for expensive masking processes, the selective deposition need not be fully selective in order to obtain the desired benefits.

In accordance with examples of the disclosure, the selective deposition processes of the present disclosure enable the selective deposition of a boron doped silicon germanium layer on a dielectric surface (surface A) relative to a semiconductor surface (surface B). In such examples, the dielectric surface (surface A) can include, but it not limited to, a silicon oxide surface (e.g., SiO₂) and/or a silicon nitride surface (e.g., Si₃N₄). Further, in such examples, the semiconductor surface (surface B) can include, but it not limited to, a silicon surface (e.g., Si).

In accordance with additional examples of the disclosure, the selective deposition processes of the present disclosure enable the selective deposition of a boron doped silicon germanium layer on a first dielectric surface (surface A) relative to a second dielectric surface (surface B). In such examples, the first dielectric surface (surface A) comprises a silicon nitride surface and the second dielectric surface (surface B) comprises a silicon oxide surface.

The selectivity of the deposition process on surface A relative to surface B can be given as a percentage calculated by [(deposition on surface A)-(deposition on surface B)]/(deposition on the surface A). Deposition can be measured in any of a variety of ways. For example, deposition may be given as the measured thickness of the deposited material, or may be given as the measured amount of material deposited. In some embodiments, the selectivity of the selective deposition of the boron doped silicon germanium layer on surface A relative to surface B is greater than 10%, greater than 50%, greater than 75%, greater than 85%, greater than 90%, greater than 93%, greater than 95%, greater than 98%, greater than 99%, greater than 99.5%, equal to about 100%.

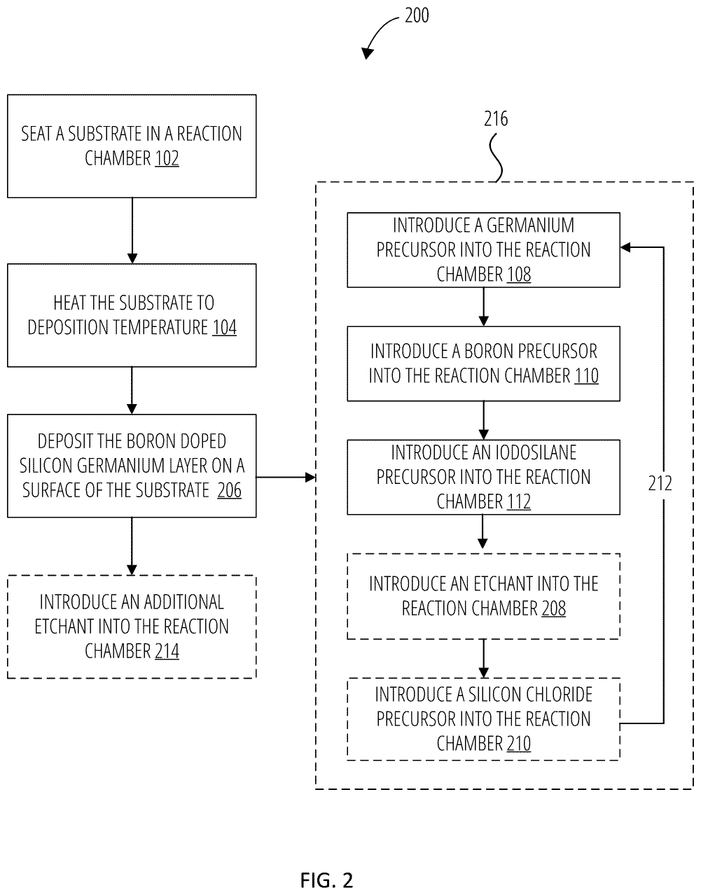

FIG. 2 illustrates exemplary method 200 for selectively depositing boron doped silicon germanium layers with both a high active dopant concentration and a high germanium content according to the embodiments of the present disclosure. Briefly, method 200 includes the steps of, seating a substrate within a reaction chamber (step 102), heating the substrate to a deposition temperature (step 104), and selectively depositing the boron doped silicon germanium layer (step 206). In some embodiments, the selective deposition process of method 200 includes, introducing a germanium precursor into the reaction chamber (step 108), introducing a boron precursor into the reaction chamber (step 110), and introducing a silicon precursor comprising an iodosilane precursor into the reaction chamber (112) as previously described. In some embodiments the selective deposition process of method 200 optionally includes the step(s) of introducing an etchant into the reaction chamber either during the deposition step 206 (e.g., by performing optional step 208) and/or after completion of the deposition step 206 (e.g., by performing optional etch step 214). In some embodiments the selective deposition process of method 200, optionally includes the step of introducing a silicon chloride precursor into the reaction chamber (step 210). As with method 100 the steps 108, 110, 112, 208, 210, and 214 of method 200 can be performed in any order or sequence, in parallel (or at least partially in parallel), and can include multiple repetitions of one or more of the steps. In accordance with additional examples of the disclosure, the selective deposition process of method 200 can optionally include a cyclical deposition process and/or a cyclical deposition-etch process, as denoted by deposition cycle loop 212, as described in greater detail below.

In accordance with examples of the disclosure, selectively depositing boron doped silicon germanium layers with both high active dopant concentration and high germanium content can include the introduction of chlorinated precursors/reactants/etchants to increase the selectivity of the deposition processes while still employing a silicon precursor comprising an iodosilane precursor. Therefore, the selective deposition process of the present disclosure can include introducing a silicon chloride precursor into the reaction chamber along with the iodosilane precursor (either together or separately) to improve deposition selectivity of the boron doped silicon germanium layer. In such examples, the silicon chloride precursor includes one or more of the silicon chloride precursors previously described above. In some embodiments, silicon chloride precursor comprises dichlorosilane (DCS). In addition, the selective deposition process of the present disclosure can employ germanium chloride compounds as at least one of the germanium precursors and boron chloride compounds as at least one of the boron precursors to further improve deposition selectivity of the boron doped silicon germanium layer. In such examples, the germanium chloride compound is selected from a group consisting of GeCl₄, GeCl₂, and GeCl₂H₂ and the boron chloride precursor is selected from a group a consisting of BH₂Cl, BCl₂H. In such examples, the germanium chloride compound can be employed in addition to or instead of a non-halide germanium precursor (e.g., GeH₄, Ge₂H₆, Ge₃H₈, GeH (Si). Further in such examples, a boron chloride compound can be employed in addition to or instead of a non-halide boron precursor (e.g., B₂H₆, B₂D₆). In addition, the selective deposition process of the present disclosure can include introducing an etchant into the reaction chamber either during deposition or post deposition (e.g., by an etch-back process) to further improve deposition selectivity of the boron doped silicon germanium layer. In some embodiments, the etchant comprises a halide etchant. In some embodiments the halide etchant comprises chlorine (Cl₂) and/or hydrochloric acid (HCl), for example.

The following detailed description of the selective deposition processes of the present disclosure do not repeat, or only briefly describe, the steps of method 200 which have been previously described in detail above in relation to method 100, such as, for examples, steps 102, 104, 108, 110, and 112. In addition, the selective deposition processes described below can also include the introduction of chlorinated precursors/reactants/etchants to increase the selectivity of the deposition processes as described above.

In some embodiments of the disclosure, method 200 comprises a non-cyclical deposition process for selectively depositing the boron doped silicon germanium layer. In such non-cyclical examples, the deposition cycle loop 212 is omitted. In such examples, deposition step 206 comprises introducing a germanium precursor into the reaction chamber, introducing a boron precursor into the reaction chamber, and introducing a silicon precursor comprising an iodosilane precursor into the reaction chamber, as previously described. In such non-cyclical examples of the disclosure, the deposition step 206 optionally includes introducing a silicon chloride precursor into the reaction chamber (step 208). In such non-cyclical examples of the disclosure, the deposition step 206 can also optionally include introducing an etchant into the reaction chamber, either during the deposition step 206 (e.g., by performing optional etch step 208) and/or after completion of the deposition step 206 (e.g., by performing optional etch step 214). In some embodiments, the etchant is introduced after deposition of the boron doped silicon germanium layer (e.g., by performing step 214 upon completion of step 206) to etch-back any unwanted boron doped silicon germanium layers thereby improving the selectivity of the deposition process.

In some embodiments of the disclosure, method 200 comprises a selective cyclical deposition process for depositing the boron doped silicon germanium layer. In such examples, the selective deposition method 200 can comprise a cyclical deposition process or a cyclical deposition-etch process. In such examples, deposition step 206 comprises one or more repeated deposition cycles 216 (including the deposition cycle loop 212) wherein a unit deposition cycle 216 includes introducing a germanium precursor into the reaction chamber, introducing a boron precursor into the reaction chamber, introducing a silicon precursor comprising an iodosilane precursor into the reaction chamber, optionally introducing a silicon chloride precursor into the reaction chamber (step 210), and optionally introducing an etchant into the reaction chamber (step 210). Each of the steps of the deposition cycle 216 can be initiated and/or terminated in any order. Further, the deposition cycle 216 can include one or more repetitions of each step (e.g., 1-10 or 1-5 repetitions) prior to proceeding to subsequent steps of the deposition cycle 216. In some embodiments, a deposition cycle can be different to a subsequent deposition cycle depending on the desired layer properties of the boron doped silicon germanium layer. In some embodiments, a deposition cycle can include one or both of the optional steps 208 and 210, whereas subsequent deposition cycles can omit one or both of the optional steps 208 and 210. In some embodiments a deposition cycle can include one or more of the steps 108, 110, and 112, whereas subsequent deposition cycles can omit one or more of the steps 108, 110, and 112. In some embodiments, one or more of the steps of the deposition cycle 216 can be performed in parallel, or at least partially in parallel. In accordance with examples of the disclosure, the deposition cycle 216 can be repeated as desired as indicated by the deposition cycle loop 212. For example, in some embodiments, the deposition cycle 216 can be repeated more than 2, 4, 6, 10, 20, 30, 40, 50, 75, or 100 times. The termination of performing the repeated deposition cycles 216 can be based on having performed a predetermined number of repetitions or upon reaching a desired thickness of the boron doped silicon germanium layer.

In accordance with examples of the disclosure, the selective deposition processes of the present disclosure enable the selective deposition of a boron doped silicon germanium layer on a dielectric surface (surface A) relative to a semiconductor surface (surface B). In such examples, the dielectric surface (surface A) can include a silicon nitride surface and/or a silicon oxide surface and the semiconductor surface (surface B) can include a silicon surface. In such examples, the boron doped silicon germanium layer is selectively deposited on surface A relative to surface B with a selectivity greater than 10%, greater than 50%, greater than 75%, greater than 85%, greater than 90%, greater than 93%, greater than 95%, greater than 98%, greater than 99%, greater than 99.5%, equal to about 100%.

In accordance with additional examples of the disclosure, the selective deposition processes of the present disclosure enable the selective deposition of a boron doped silicon germanium layer on a first dielectric surface (surface A) relative to a second dielectric surface (surface B). In such examples, the first dielectric surface (surface A) comprises a silicon nitride surface and the second dielectric surface (surface B) can comprises a silicon oxide surface. In such examples, the boron doped silicon germanium layer is selectively deposited on surface A relative to surface B with a selectivity greater than 10%, greater than 50%, greater than 75%, greater than 85%, greater than 90%, greater than 93%, greater than 95%, greater than 98%, greater than 99%, greater than 99.5%, equal to about 100%.

Various embodiments of the present disclosure also relate to the boron doped silicon germanium layers deposited by the methods described above.

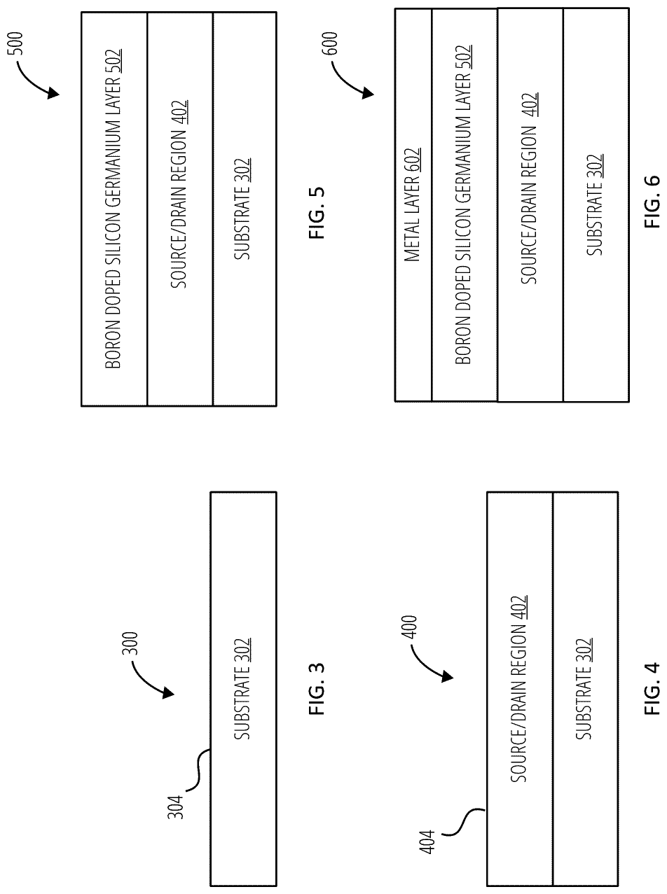

In accordance with examples of the disclosure, FIG. 3 illustrates a structure 300 which comprises a substrate 302 including a surface 304. In some embodiments the boron doped silicon germanium layers of the present disclosure are deposited directly on surface 304 of the substrate 302. As a non-limiting example, surface 304 can include one or more of silicon, silicon germanium, silicon oxide, or silicon nitride, for example.

In accordance with further examples of the disclosure, FIG. 4 illustrates a structure 400 which includes the substrate 302 and a source/drain region 402 of a device structure. In such examples, the source/drain region 402 can comprise a silicon germanium source/drain region including one or more layers of silicon germanium of various compositions, thicknesses, and doping concentrations. In such examples, the source/drain region 402 includes surface 404. Further in such examples, surface 404 comprises a silicon germanium surface. In other examples, surface 404 includes one or more of a silicon surface, a silicon oxide, a silicon nitride surface, and a silicon germanium surface.

In accordance with further examples of the disclosure, FIG. 5 illustrates a structure 500 which includes the previously described substrate 302 and source/drain region 402. In such examples, the structure 500 includes a boron doped silicon germanium layers 502 deposited by the methods of the present disclosure. In some embodiments the boron doped silicon germanium layer 502 is epitaxially deposited directly on the surface 404 of the source/drain region 402. In some embodiments, the boron doped silicon germanium layer 502 has a different composition and/or lattice constant to the underlying source/drain region 402. In some embodiments, the boron doped silicon germanium layer 502 has a first germanium concentration and the source/drain region 402 comprises a silicon germanium layer with a second germanium concentration different to the first germanium concentration. In some embodiments, the boron doped silicon germanium layer 502 is lattice matched to the underlying source/drain region 402. In some embodiments, the boron doped silicon germanium layer 502 is fully strained to the underlying source/drain region 402 and is substantially free of misfit type dislocations.

In accordance with examples of the disclosure, the boron doped silicon germanium layer 502 has an average layer thickness of less than 20 nm, less than 15 nm, less than 10 nm, less than 7 nm, or less than 5 nm. In some embodiments, the boron doped silicon germanium layers 502 has an average layer thickness between 5 nm and 20 nm.

In accordance with examples of the disclosure, the boron doped silicon germanium layer 502 has a high boron dopant concentration and a resulting high active dopant concentration. In such examples, the boron doped silicon germanium layer 502 has an active dopant concentration greater than 2.0×10²¹ cm⁻³, greater than 2.5×10²¹ cm⁻³, greater than 3.0×10²¹ cm⁻³, greater than 3.5×10²¹ cm⁻³, greater than 4.0×10²¹ cm⁻³, greater than 4.5×10²¹ cm⁻³, or greater than 5.0×10²¹ cm⁻³. In such examples, the boron doped silicon germanium layer 502 also has a high germanium content. For example, the boron doped silicon germanium layer 502 has a germanium concentration (atomic-%) greater than 50%, greater than 55%, greater than 60%, greater than 65%, greater than 70%, greater than 75%, greater than 80%, greater than 85%, or greater than 90%.

In accordance with further examples of the disclosure, FIG. 6 illustrates a structure 600 which includes the previously described substrate 302, source/drain region 402, and the boron doped silicon germanium layer 502. Structure 600 also includes a metal layer 602 formed on (or directly on) the boron doped silicon germanium layer 502. In such examples, the boron doped silicon germanium layer 502 comprises a contact layer and the metal layer 602 can comprise an electrode for providing electrical contact to the boron doped silicon germanium layer 502 (and underlying layers). In some embodiments structure 600 comprises a portion of a transistor device structure, such as, for example, a gate-all-around device structure, a nanosheet device structure, a forksheet device structure, and a complementary FET (CFET) device structure.

Various embodiments of the present disclosure also relate to a composition (e.g., a deposition gas composition or deposition gas formulation) for depositing the boron doped silicon germanium layers of the present disclosure.

In accordance with examples of the disclosure, the embodiments of the present disclosure include a composition for the epitaxial deposition of a boron doped silicon germanium layer with both an active dopant concentration greater than 3×10²¹ cm⁻³ and a germanium content greater than 50 atomic-%. In such examples, the composition comprises an iodosilane precursor having less than 1% metal impurities and less than 1% phosphorous impurities. In some embodiments, the composition comprises an iodosilane precursor having less than 1.5% metal impurities, less than 1% metal impurities, less than 0.8% metal impurities, less than 0.5% metal impurities, or less than 0.3% metal impurities. In some embodiments, the composition comprises an iodosilane precursor having less than 1.5% phosphorous impurities, less than 1% phosphorous impurities, less than 0.8% phosphorous impurities, less than 0.5% phosphorous impurities, or less than 0.3% phosphorous impurities. In some embodiments, the composition comprises an iodosilane precursor having less than 1.5% carbon impurities, less than 1% carbon impurities, less than 0.8% carbon impurities, less than 0.5% carbon impurities, or less than 0.3% carbon impurities. In some embodiments, the composition comprises an iodosilane precursor having less than 1.5% carbon impurities, less than 1% oxygen impurities, less than 0.8% oxygen impurities, less than 0.5% oxygen impurities, or less than 0.3% oxygen impurities.

In some embodiments, the composition consists essentially of the iodosilane precursor, a germanium precursor, a boron precursor, and one or more additional inert gases. In such embodiments, the composition has less than less than 1.5% metal impurities, less than 1% metal impurities, less than 0.8% metal impurities, less than 0.5% metal impurities, or less than 0.3% metal impurities. Further, in such embodiments, the composition has less than 1.5% phosphorous impurities, less than 1% phosphorous impurities, less than 0.8% phosphorous impurities, less than 0.5% phosphorous impurities, or less than 0.3% phosphorous impurities. Further, in such embodiments, the composition has less than 1.5% carbon impurities, less than 1% carbon impurities, less than 0.8% carbon impurities, less than 0.5% carbon impurities, or less than 0.3% carbon impurities. Further, in such embodiments, the composition has less than 1.5% oxygen impurities, less than 1% oxygen impurities, less than 0.8% oxygen impurities, less than 0.5% oxygen impurities, or less than 0.3% oxygen impurities.

In some embodiments, the iodosilane precursor is diiodosilane. In some embodiments, the iodosilane precursor is monoiodosilane. In some embodiments, the composition includes an additional silicon precursor. In some embodiments, the composition includes a germanium precursor comprising a germanium chloride compound selected from a group consisting of GeCl₄, GeCl₂, and GeCl₂H₂. In some embodiments, the composition includes a boron precursor comprising a boron chloride compound selected from a group consisting of BH₂Cl, BCl₂H, and BCl₃. In some embodiments, the one or more additional inert gases include at least one of nitrogen, argon, and helium.

In accordance with further examples of the disclosure, the composition enables the boron doped silicon germanium layer to be deposited at a rate greater than 0.5 nm/min, greater than 1 nm/min, greater than 1.5 nm/min, greater than 2 nm/min, greater than 2.5 nm/min, greater than 3 nm/min, greater than 4 nm/min, greater than 5 nm/min, greater than 6 nm/min, greater than 8 nm/min, or greater than 10 nm/min, or between 1 nm/min and 10 nm/min. It should be noted that the growth rate is dependent a number of factors including, not limited to, the composition, the deposition temperature, reaction chamber pressure, and germanium composition. In some embodiments, the composition comprises a silicon precursor consisting of diiodosilane and the boron doped silicon germanium layers 502 is deposited at a rate greater than 0.5 nm/min, greater than 1 nm/min, greater than 1.5 nm/min, greater than 2 nm/min, greater than 2.5 nm/min, greater than 3 nm/min, greater than 4 nm/min, greater than 5 nm/min, greater than 6 nm/min, greater than 8 nm/min, or greater than 10 nm/min, or between 1 nm/min and 10 nm/min. In some embodiments, the composition comprises a silicon precursor consisting of monoiodosilane and the boron doped silicon germanium layers 502 is deposited at a rate greater than 0.5 nm/min, greater than 1 nm/min, greater than 1.5 nm/min, greater than 2 nm/min, greater than 2.5 nm/min, greater than 3 nm/min, greater than 4 nm/min, greater than 5 nm/min, greater than 6 nm/min, greater than 8 nm/min, or greater than 10 nm/min, or between 1 nm/min and 10 nm/min. In such examples, the composition enables the boron doped silicon germanium layer to be deposited at a deposition temperature between 250° C. and 400° C. In such examples, the composition enables the boron doped silicon germanium layer to be deposited as a fully strained layer, i.e., free of strain relaxation and any associated misfit type dislocations. In such examples, the composition enables the boron doped silicon germanium layer to be deposited without significantly depositing a parasitic boron doped silicon germanium layer on the surfaces of the reaction chamber. In such examples, the composition enables the boron doped silicon germanium layer to be deposited with a germanium composition greater than 50 atomic-% with an active donor concentration greater than 3×10²¹ cm⁻³.

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method of thermally depositing a boron doped silicon germanium layer with both a high active dopant concentration and a high germanium content, the method comprising:
seating a substrate in a reaction chamber;
heating the substrate to a deposition temperature; and
depositing the boron doped silicon germanium layer on a surface of the substrate by an epitaxial deposition process comprising:
introducing a germanium precursor into the reaction chamber;
introducing a boron precursor into the reaction chamber; and
introducing a silicon precursor comprising an iodosilane precursor into the reaction chamber.

2. The method of claim 1, wherein the deposition temperature is between 250° C. and 400° C.

3. The method of claim 1, wherein the germanium precursor comprises a germanium chloride compound selected from the group consisting of GeCl₄, GeCl₂, and GeCl₂H₂.

4. The method of claim 1, wherein the boron precursor comprises a boron chloride compound selected from the group consisting of BH₂Cl, BCl₂H, and BCl₃.

5. The method of claim 1, wherein the iodosilane precursor is selected from the group consisting of monoiodosilane, diiodosilane, triiodosilane, tetraiodosilane.

6. The method of claim 1, wherein the iodosilane precursor consists of diiodosilane.

7. The method of claim 1, wherein the iodosilane precursor consists of monoiodosilane.

8. The method of claim 1, wherein the substrate comprises a silicon germanium source/drain region and the boron doped silicon germanium layer is epitaxially deposited directly on the silicon germanium source/drain region.

9. The method of claim 1, wherein the boron doped silicon germanium layer has both an active dopant concentration greater than 3×10²¹ cm⁻³ and a germanium content greater than 50 atomic.

10. The method of claim 1, wherein the epitaxial deposition process is a selective deposition process which selectively deposits the boron doped silicon germanium layer on a surface A relative to a surface B, wherein the surface A is a silicon nitride surface and the surface B is a silicon oxide surface, or wherein the surface A is silicon oxide surface or a silicon nitride surface and the surface B is a silicon surface.

11. The method of claim 10, further comprising introducing an etchant into the reaction chamber.

12. The method of claim 11, wherein the selective deposition process further comprises a cyclical deposition process or a cyclical deposition-etch process.

13. The method of claim 2, wherein the boron doped silicon germanium layer is deposited with an average layer thickness between 5 nm and 20 nm at growth rate between 1 nm/min and 10 nm/min.

14. A method of forming a contact layer to a silicon germanium source/drain region, the method comprising:
seating a substrate in a reaction chamber, the substrate comprising one or more silicon germanium source/drain regions;
heating the substrate to a deposition temperature between 250° C. and 400° C.; and
depositing a boron doped silicon germanium layer on the silicon germanium source/drain region by an epitaxial deposition process by introducing a single silicon precursor comprising an iodosilane precursor, a germanium precursor, and a boron precursor into the reaction chamber,
wherein the boron doped silicon germanium layer has both an active dopant concentration greater than 3×10²¹ cm⁻³ and a germanium content greater than 50 atomic.

15. The method of claim 14, wherein at least one of the germanium precursor and the boron precursor comprise chloride compounds.

16. The method of claim 14, wherein the epitaxial deposition process is a selective deposition process which selectively deposits the boron doped silicon germanium layer on a surface A relative to a surface B, wherein the surface A is a silicon nitride surface and the surface B is a silicon oxide surface, or wherein the surface A is a silicon oxide surface or a silicon nitride surface and the surface B is a silicon surface.

17. The method of claim 16, further comprising introducing an etchant into the reaction chamber.

18. The method of claim 1, wherein the iodosilane precursor consists of diiodosilane or monoiodosilane.

19. A composition for epitaxial deposition of a boron doped silicon germanium layer with both an active dopant concentration greater than 3×10²¹ cm⁻³ and a germanium content greater than 50 atomic, the composition comprising an iodosilane precursor having less than 1% metal impurities and less than 1% phosphorous impurities.

20. The composition of claim 19, wherein the composition consists essentially of the iodosilane precursor, a germanium precursor, a boron precursor, and one or more additional inert gases.
